(19) United States
(12) Patent Application Publication
(10) Pub. No.: US 2013/0027034 A1
(43) Pub. Date: Jan. 31, 2013

(54) NUCLEAR MAGNETIC RESONANCE MAGNETOMETER EMPLOYING OPTICALLY INDUCED HYPERPOLARIZATION

(71) Applicants: Daniel R. Elgort, New York, NY (US); Lucian Remus Albu, Forest Hills, NY (US)

(72) Inventors: Daniel R. Elgort, New York, NY (US); Lucian Remus Albu, Forest Hills, NY (US)

(73) Assignee: KONINKLIJKE PHILIPS ELECTRONICS N.V., EINDHOVEN (NL)

(21) Appl. No.: 13/640,052

(22) PCT Filed: Mar. 18, 2011
(86) PCT No.: PCT/IB11/51144

§ 371 Date: Oct. 9, 2012

Related U.S. Application Data
(60) Provisional application No. 61/326,775, filed on Apr. 22, 2010.

(51) Int. Cl. G01R 33/26

(52) U.S. Cl. 324/301

(57) ABSTRACT

A magnetometer includes: a sample (10) comprising a selected nuclear species; an optical source (12) configured to hyperpolarize the selected nuclear species of the sample by illuminating the sample with optical radiation (14) having orbital angular momentum; a radio frequency generator (20, 26, 30, 150, 152) configured to input radio frequency energy (32) to the hyperpolarized selected nuclear species of the sample over a probed range of radio frequencies; a detector (20, 26, 40, 150, 154, 164, 166) configured to detect a frequency of nuclear magnetic resonance excited in the hyperpolarized selected nuclear species of the sample by the input radio frequency energy; and a signal output generator (64, 66) configured to output a signal indicative of magnetic field strength based on the detected frequency of nuclear magnetic resonance.

The following relates to the magnetic arts, magnetometer arts, magnetic measurement arts, and related arts.

A magnetometer is a device for measuring the strength of a magnetic field. Magnetometers have a diversity of applications, for example in healthcare, industrial, and laboratory applications. Some illustrative magnetometer applications include: magnetic field mapping for magnetic resonance (MR) scanners, synchrotrons, particle accelerators, and other devices employing magnets; detecting underground ores, minerals, unexploded mines, or submarines in the ocean; performing geological and archaeological surveys; performing measurements in a magnetic astronomical observatory; monitoring heart and brain activity; measuring flux distribution inside superconductors; retrieving data stored on magnetic media; directing vehicles on magnetic tracks; providing input to navigation systems; serving as proximity sensors; and counting items on production lines.

Nuclear magnetic resonance (NMR) magnetometers are generally considered to be the “gold standard” for performing field measurements, because NMR is the most accurate field measurement method available. Indeed, NMR magnetometers can achieve accuracies of up to 0.1 ppm. Additionally, NMR provides inherent measurements of the absolute magnetic field strength, whereas other magnetic field measurement techniques typically measure relative field strength and accordingly entail calibration procedures which are prone to errors and can lead to a bias in the measurement.

An NMR magnetometer takes advantage of the fundamental relationship F=γB between the processional frequency (F) of nuclear spins and an applied external magnetic field (B). The parameter γ is the gyrometric ratio, and is a property of a given nuclei species. For example, the gyromagnetic ratio of ¹H hydrogen nuclei is 42.577 MHz/Tesla. In operation, an NMR magnetometer determines the field strength of an unknown magnetic field by placing a small amount of a liquid sample or other sample inside the magnetic field. The sample contains nuclei having a known gyromagnetic ratio. Thus, by measuring the precessional frequency (F) and knowing the gyrometric ratio (γ), the magnetic field strength (B) is determined as B=F/γ.

A limitation of NMR magnetometers is that they have difficulty measuring weak magnetic fields. As the magnetic field gets weaker, the sample size (and therefore the size of the measurement probe of the NMR magnetometer) becomes larger. A lower limit on sample size is set by signal intensity and signal-to-noise (SNR) requirements, as well as by and practical manufacturing considerations. An upper limit on the measurement probe size is imposed by the desire to have a homogeneous magnetic field within the volume of the probe.

In some NMR magnetometer designs, these limitations of conventional NMR magnetometers are mitigated by “pre-polarizing” the measurement probe sample. Pre-polarizing the sample before using it to measure the strength of a magnetic field enables substantially weaker magnetic fields to be measured, and/or enables the use of substantially smaller probes. Using smaller probes also makes the measurement less sensitive to magnetic field inhomogeneities or gradients, enables measurements to be made in smaller spaces, and enables higher spatial resolution field maps to be measured.

Some pre-polarization methods employ the Overhauser effect. Such “Overhauser magnetometers” take advantage of a phenomenon that affects hydrogen atoms. High frequency radio frequency (RF) power, in the presence of a weak magnetic field, is used to excite unpaired electrons of a small amount of a secondary liquid that is added to the primary liquid sample that contains the hydrogen atoms. This excited electrons cause the hydrogen nuclei in the rest of the liquid to become polarized via the “Overhauser effect” See, e.g. Aspinall et al., “Magnetometry for Archaeologists”, (Rowman & Littlefield Publishers, Inc, 2008) at pages 47-48. Overhauser magnetometers are energy efficient and have sensitivities suitable for earth field measurement. Power consumption in an Overhauser magnetometer can be optimized to be as low as 1 W for continuous operation, yielding sensitivities between 0.1 nT to 0.01 nT, and sampling rates as high as 5 Hz.

The following provides new and improved apparatuses and methods which overcome the above-referenced problems and others.

In accordance with one disclosed aspect, an apparatus comprises a magnetometer that includes: a sample comprising a selected nuclear species; an optical source configured to hyperpolarize the selected nuclear species of the sample by illuminating the sample with optical radiation having orbital angular momentum; a radio frequency generator configured to input radio frequency energy to the hyperpolarized selected nuclear species of the sample over a probed range of radio frequencies; a detector configured to detect a frequency of nuclear magnetic resonance excited in the hyperpolarized selected nuclear species of the sample by the input radio frequency energy; and a signal output generator configured to output a signal indicative of magnetic field strength based on the detected frequency of nuclear magnetic resonance.

In accordance with another disclosed aspect, a method comprises: hyperpolarizing a selected nuclear species of a sample by illuminating the sample with optical radiation having orbital angular momentum; generating nuclear magnetic resonance of the hyperpolarized selected nuclear species of the sample; determining a frequency of the generated nuclear magnetic resonance; and outputting a signal indicative of magnetic field strength based on the determined frequency of the generated nuclear magnetic resonance.

One advantage resides in improved magnetometer sensitivity.

Another advantage resides in providing a magnetometer with a reduced probe size.

Another advantage resides in improved magnetometer spatial resolution.

Further advantages will be apparent to those of ordinary skill in the art upon reading and understanding the following detailed description.

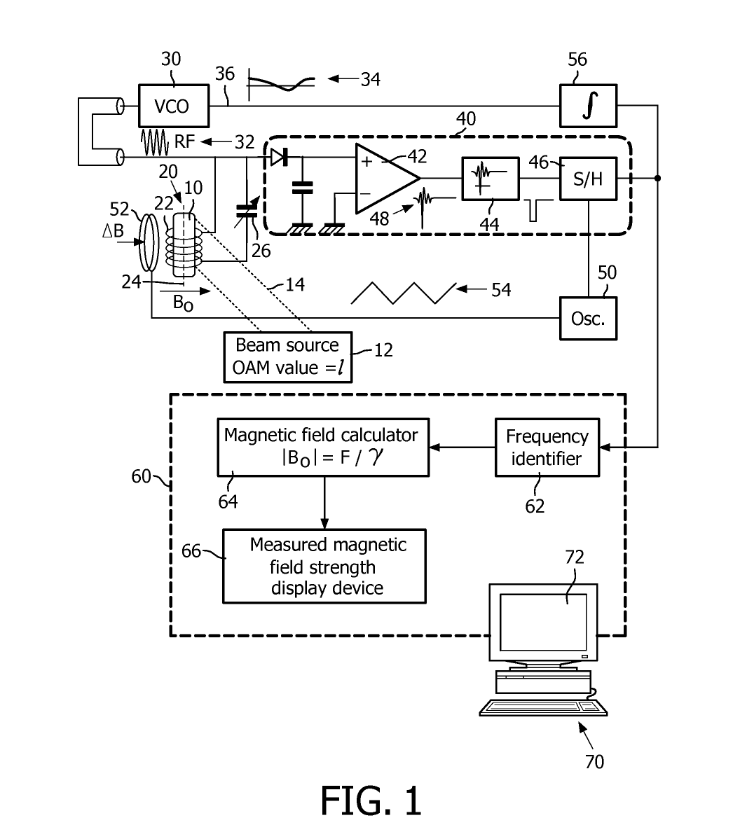

FIG. 1 diagrammatically illustrates an embodiment of a magnetometer.

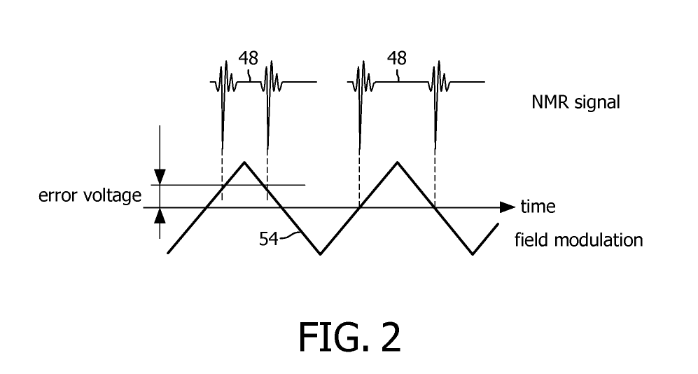

FIG. 2 diagrammatically illustrates selected signals generated by the magnetometer of FIG. 1.

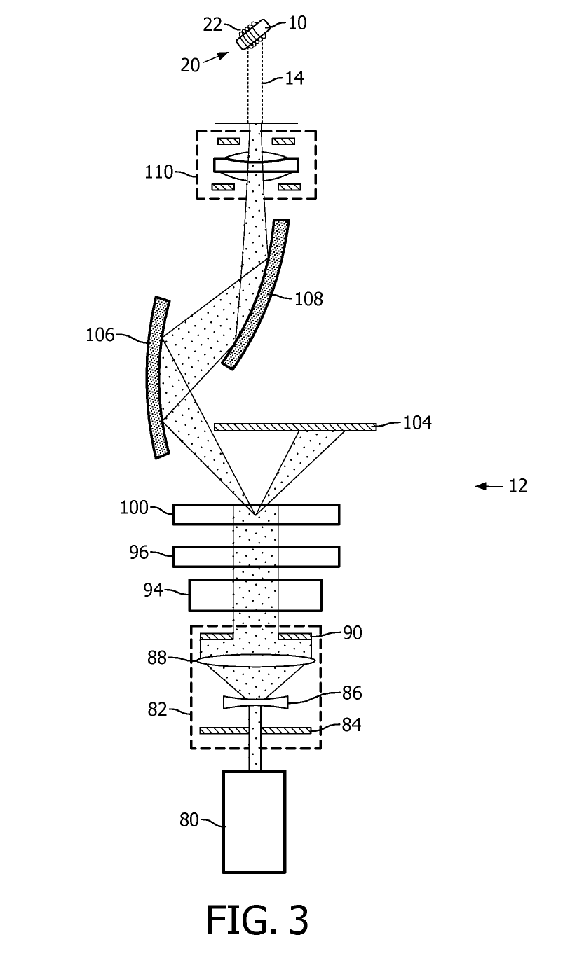

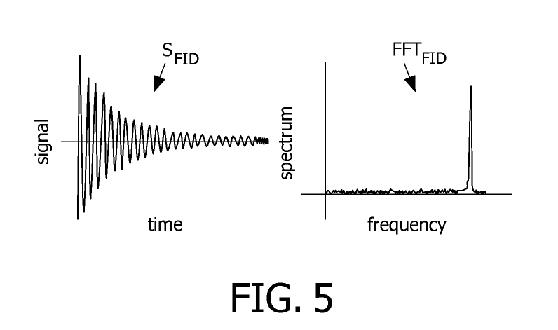

FIG. 3 diagrammatically illustrates an embodiment of a light source suitably used in the magnetometer of FIG. 1 or in the magnetometer of FIG. 5.

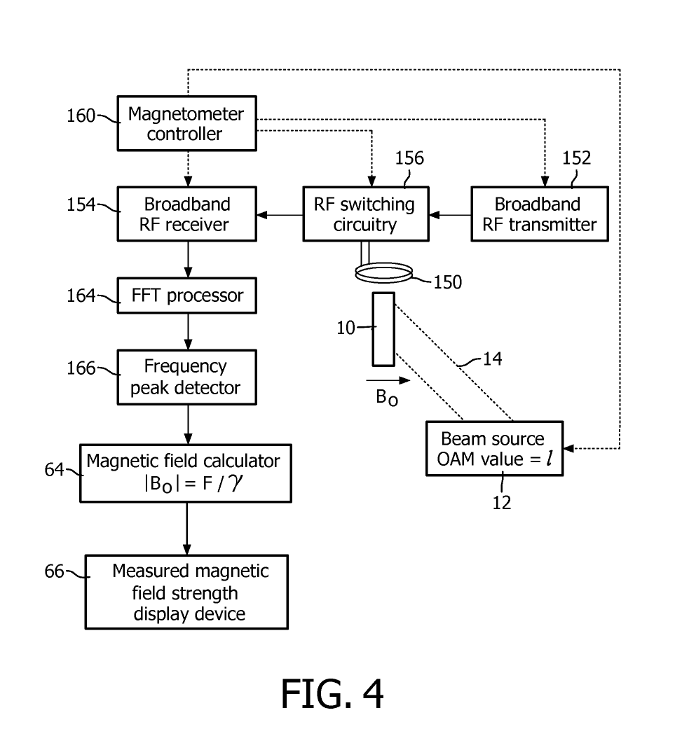

FIG. 4 diagrammatically illustrates an embodiment of a magnetometer.

FIG. 5 diagrammatically illustrates selected signals generated by the magnetometer of FIG. 5.

The nuclear magnetic resonance (NMR) magnetometers disclosed herein employ hyperpolarization of a selected nuclear species by illuminating a sample including the selected nuclear species with optical radiation having orbital angular momentum (OAM). Light (which, as used herein, encompasses electromagnetic radiation including, for example, visible light, infrared light, or ultraviolet light) having OAM can be generated in various ways, such as by suitable configurations of one or more birefringent plates, polarizers, lenses, phase plates, space light modulators, phase holograms, or so forth. Some suitable approaches for generating light having OAM are disclosed, for example, in: Santamoto, “Photon orbital angular momentum: problems and perspectives”, Fortschr. Phys. vol. 52 no. 11-12, pages 1141-53 (2004); Elgort et al., WO 2009/081360 A1; Albu et al., WO 2009/090609 A1; and Albu et al., WO 2009/090610 A1; each of which is incorporated herein by reference in its entirety.

Because angular momentum is a conserved quantity, the OAM of photons absorbed by molecules is transferred in whole to interacting molecules. As a result, affected electron states reach saturated spin states, angular momentum of the molecule about its own center of mass is increased and oriented along the propagation axis of the incident light, and magnetons precession movement of the molecules are also oriented along the propagation axis of the incident light. These effects make it possible to hyperpolarize nuclei within fluids (or, more generally, matter) by illumination with light that carries spin and OAM. In a light beam there is a flow of electromagnetic energy with one component that travels along the vector of the beam propagation, and a second component that rotates about the axis of the beam propagation. The second component is proportional to the angular change of the potential vector around the beam propagation. The rotational energy flow is proportional to a quantiative OAM value, denoted herein as l, and the rotational energy transferred to molecules with which the light interacts is increased with the value of the OAM value l. Since angular momentum is a conserved quantity, when light carrying spin and OAM is absorbed by molecules of matter, the total angular momentum of the system (including both the radiation and the matter) is not changed during absorption and emission of radiation. When a photon is absorbed by an atom, its angular momentum is transferred to the atom. The resulting angular momentum of the atom is then equal to the vector sum of its initial angular momentum plus the angular momentum of the absorbed photon.

Generally, a molecule includes both a nucleus and coupled electrons, and there are both nuclear angular momentum and electron angular momentum types. When a photon interacts with the molecule, the OAM of the electrons is directly coupled to the optical transitions. The different types of angular momentum, however, are coupled to each other by various interactions that allow the polarization to flow from the photon through the electron orbital to nuclear spin, electron spin and molecular rotation reservoirs. See Elgort et al., WO 2009/081360 A1; Albu et al., WO 2009/090609 A1; and Albu et al., WO 2009/090610 A1; each of which is incorporated herein by reference in its entirety. The magnitude of the interaction between the photon and the molecule is proportional to the OAM of the photon. Resultantly, the molecular rotation value and orientation changes to tend to align along the direction of propagation of the light, and tend to align molecular nuclei along the same direction. The momenta of molecules are changed in that they are biased toward alignment in a direction along the propagation axis of the incident light by light endowed with spin and OAM proportional to the OAM content of the light.

With reference to FIG. 1, an illustrative magnetometer employing a continuous wave (CW) measurement approach is diagrammatically illustrated. A sample 10 comprises a selected nuclear species in which NMR is excited to perform a magnetic field strength measurement. The nuclear species may, for example, be an isotope selected from Table 1, which lists some atomic species suitably used as target samples for an NMR magnetometer. Table 1 is not exhaustive, and other nuclear species not listed in Table 1 may also be employed. The choice of the target sample to use in the NMR magnetometer is influenced by the range of magnetic field strengths that are intended to be measured. It is typically advantageous to keep the operational frequency range of an NMR magnetometer within relatively narrow band and at frequencies that are neither too low nor too high. For example, when measuring fields that are between 0.04 to 2T, ^{I}H nuclei are commonly used in the form of water. When measuring magnetic fields between 2T and 14T, ²H nuclei in the form of heavy water containing ²H₂O molecules are suitable. It is to be understood that the sample 10 includes the target or selected nuclear species, but may optionally also include other atoms, molecules, or substances. For example, in the case of water comprising ¹H nuclei, the sample 10 also includes oxygen atoms which are part of the water (H₂O) molecules; similarly, in the case of heavy water comprising ²H nuclei the sample 10 typically also includes both oxygen and a substantial fraction of the hydrogen atoms in the form of ¹H nuclei. In some embodiments, the sample 10 may comprise water or another solvent in which a solute that includes the target or selected nuclear species is dissolved. In general, the sample 10 is in liquid form as this phase can provide substantial homogeneity and high molecular packing density; however, the sample 10 may also be a solid, gas, or other phase of matter. As indicated in Table 1, the selection of the target or selected nuclear species determines the gyrometric ratio (γ).

TABLE 1

| | gyrometric | |
|---|---|---|
| Isotope | ratio (γ) | |
| ¹H | 42.576396 | MHz/T |
| ²H | 6.535 | MHz/T |
| ¹³C | 10.71 | MHz/T |
| ¹⁴N | 3.08 | MHz/T |
| ¹⁹F | 40.08 | MHz/T |
| ²³Na | 11.27 | MHz/T |
| ²⁷Al | 11.093 | MHz/T |
| ³¹P | 17.25 | MHz/T |

An optical source 12 is configured to hyperpolarize the selected nuclear species of the sample 10 by illuminating the sample 10 with optical radiation 14 having orbital angular momentum (OAM). The optical source 12 can employ any suitable method for imparting to the light beam 14 orbital angular momentum of a selected OAM value (l). For example, some suitable approaches for generating light having OAM are disclosed, for example, in: Santamoto, “Photon orbital angular momentum: problems and perspectives”, Fortschr. Phys. vol. 52 no. 11-12, pages 1141-53 (2004); Elgort et al., WO 2009/081360 A1; Albu et al., WO 2009/090609 A1; and Albu et al., WO 2009/090610 A1; each of which is incorporated herein by reference in its entirety. An illustative embodiment of the optical source 12 is set forth elsewhere herein with reference to FIG. 3. The selection of the orbital angular momentum l, that is, the OAM value (l) is not critical, but in general a larger selected OAM value (l) produces a higher degree of hyperpolarization. In some embodiments the optical source 12 is configured to hyperpolarize the selected nuclear species of the sample 10 by illuminating the sample with optical radiation having orbital angular momentum l of at least l=10, which is effective for producing substantial hyperpolarization so as to enhance magnetometer sensitivity. As mentioned previously, the light 14 having OAM may be visible light, infrared light, ultraviolet light, or so forth. The spectrum of the light 14 can be monochromatic, broadband (e.g., white light), or so forth. The photon energy or energies of the spectrum of the light 14 having OAM should be selected so that the photons are strongly absorbed by the target or selected nuclear species. If the sample 10 includes molecules separate from the target or selected nuclear species (for example, in the case of a solute containing the target or selected nuclear species dissolved in a solvent) then the photon energy or energies of the spectrum of the light 14 having OAM is optionally also selected to provide strong light absorption by the target or selected nuclear species as compared with the molecules that are separate from the target or selected nuclear species (e.g., the solvent).

As diagrammatically indicated in FIG. 1, a magnetic field B₀ is to be measured by the magnetometer. The magnetic field B₀ has magnitude |B₀| (to be measured) and a direction. In the illustrative example, the magnetic field B₀ has a horizontal direction as diagrammatically depicted in FIG. 1. The illustrative vector representing B₀ is shown in FIG. 1 outside of the sample 10 for illustrative convenience—however, it is to be understood that the magnetometer measures the magnitude |B₀| of the magnetic field B₀ within the volume of the sample 10. If the magnetic field to be measured is spatially inhomogeneous, it is advantageous for the sample 10 to have a small volume so that the magnetometer measures the magnetic field strength at what is approximately a “point” in space. Toward this end, the volume of the sample 10 is optionally small. For example, in some embodiments the sample 10 has a volume of about 100 cubic microns or less. As another example, in some embodiments the sample 10 has a volume of about 10 cubic microns or less. These small sample volumes are enabled because the hyperpolarization of the selected nuclear species provided by the illumination 14 having OAM substantially enhances the sensitivity of the magnetometer. In general, there is a tradeoff between sensitivity and the volume of the sample 10—thus, in other embodiments the sample 10 may be made substantially larger than 10 cubic microns, or even larger than 100 cubic microns, in order to provide sensitivity effective for measuring low magnetic field strength.

With continuing reference to FIG. 1, in the illustrative CW measurement configuration the sample 10 is made part of a resonant electrical circuit. For example, the resonant electrical circuit can include: (i) an inductor 20 having a coil 22 and the sample 10 as a core of the coil 22 (illustrated embodiment); or (ii) a capacitor having conductive plates and the sample as a dielectric spacer (embodiment not illustrated); or so forth. In the latter illustrative embodiment employing a capacitor, one or both conductive plates is suitably a grid or other “open” configuration to enable optical illumination of the sample by the optical source 12. In the illustrated embodiment of the inductor 20, the windings of the coil 22 are similarly “open”, or alternatively the optical source can illuminate the sample along the direction of the coil axis 24 of the coil 22 so that the windings do not block the light having OAM. The illustrative resonant circuit is a series resonant LC circuit including the inductor 20 and a capacitor 26 that can be trimmed to tune the center frequency of the resonant LC circuit. Other resonant circuit configurations besides the illustrative resonant series LC circuit are also contemplated.

The resonant circuit 20, 26 is a component of a radio frequency generator configured to input radio frequency energy to the hyperpolarized selected nuclear species of the sample over a probed range of radio frequencies. The radio frequency generator includes the resonant circuit 20, 26 and a voltage controlled oscillator (VCO) 30 that drives the resonant circuit 20, 26 with input radio frequency energy 32 (diagrammatically indicated in FIG. 1) whose radio frequency is controlled by an input voltage 34 (diagrammatically indicated in FIG. 1) supplied at an input 36 of the VCO 30. The frequency of the input radio frequency energy 32 is swept over the probed range of radio frequencies, where the probed range of radio frequencies is chosen to encompass the range of frequencies F=γ|B₀| corresponding to the expected range of magnetic field strengths |B₀| for the magnetic field B₀ to be measured by the magnetometer.

The resonant circuit 20, 26 is also part of a detector including the resonant circuit 20, 26 and a readout sub-circuit 40 that in the illustrated embodiment is based on an operational amplifier (op-amp) 42 and also includes a threshold detector 44 and a sample-and-hold (S/H) element 46. The detector is configured to detect a frequency of NMR excited in the hyperpolarized selected nuclear species of the sample 10 by the input radio frequency energy 32 based on correlation of a resonance of the resonant electrical circuit 20, 26 with a sweep of input radio frequency energy 32 over the probed range of radio frequencies. When the frequency of the input radio frequency energy 32 equals the NMR frequency (F=γ|B₀|) for the selected nuclear species in the magnetic field B₀ to be measured, the resonant LC circuit 20, 26 absorbs part of the input radio frequency energy 32 which results in a decrease in the transmission of the input radio frequency energy 32 to the readout sub-circuit 40. This results in the diagrammatically illustrated NMR signal 48 having a sharp signal decrease at the time when the frequency of the frequency-swept input radio frequency energy 32 matches the NMR frequency. This sharp signal decrease is detected by the threshold detector 44 and sampled by the S/H element 46.

In some embodiments, the radio frequency generator comprising the resonant LC circuit 20, 26 and VCO 30 is driven in an open-loop fashion by the input voltage 34 (diagrammatically indicated in FIG. 1) supplied at the input 36 of the VCO 30, with the input voltage 34 being a sinusoidal, triangular, or other time-varying voltage, and the detector comprising the resonant LC circuit 20, 26 and readout sub-circuit 40 generates the output via the S/H circuit 46 from which the NMR frequency can be determined by correlation with the VCO frequency.

With continuing reference to FIG. 1 and with further reference to FIG. 2, in the illustrative embodiment, however, the radio frequency generator and the detector are interconnected in a CW Q-meter configuration such that the frequency of the input radio frequency energy 32 is latched to the NMR frequency and tracks the NMR frequency if it changes with time due to changes in the magnetic field strength |B₀|. Toward this end, an oscillator 50 is operatively connected with a radio frequency coil or antenna 52 arranged respective to (e.g., proximate to) the sample 10 to deliver a modulation magnetic field ΔB oriented parallel (or anti-parallel) with the magnetic field B₀ to be measured, as diagrammatically shown in FIG. 1. Thus, the modulation magnetic field ΔB adds (in a vector sense) to the magnetic field B₀ whose stength |B₀| is to be measured, and the total magnetic field experienced by the sample 10 at any given instant in time is B₀+ΔB. The modulation magnetic field ΔB is modulated using a diagrammatically indicated symmetric triangle-wave modulation 54. The modulation magnetic field ΔB together with feedback control of the VCO 30 via a feedback loop sub-circuit 56 (which employs integral feedback control, in the diagrammatic embodiment) provides the Q-meter configuration in which the frequency of the input radio frequency energy 32 is latched to and tracks the NMR frequency and tracks the NMR frequency. As diagrammatically shown in FIG. 2, the resonance peaks of the NMR signal 48 detected during the field modulation 54 generate an error voltage proportional to the distance of the peaks from the zero-crossing of the field modulation 54. This error voltage is used in the Q-meter configuration of FIG. 1 to generate a negative feed-back signal that serves as the input voltage 34 supplied at the input 36 of the VCO 30. The Q-meter configuration described herein with reference to FIGS. 1 and 2 is further described in Bottura et al., “Field Measurements”, Proceedings of the CERN Accelerator School (CAS) on Superconductivity, page 18 (2002), which is incorporated herein by reference in its entirety.

The radio frequency generator and the detector shown in FIG. 1 are illustrative examples. More generally, any generator/detector circuit configuration can be employed which functions to (i) input radio frequency energy to the hyperpolarized selected nuclear species of the sample and sweep the frequency of the input radio frequency energy over a range of radio frequencies encompassing the expected NMR frequency and (ii) detect the NMR frequency.

With continuing reference to FIG. 1, a magnetic field readout device 60 is configured to output a signal indicative of magnetic field strength based on the detected NMR frequency. Toward this end, a frequency identifier 62 generates a quantitative representation of the NMR frequency detected by the detector comprising the resonant circuit 20, 26 and readout sub-circuit 40. A magnetic field calculator 64 determines the magnetic field strength |B₀| based on the relationship |B₀|=F/γ where F is the detected NMR frequency and γ is the gyrometric ratio for the target or selected nuclei of the sample 10. A display device 66 shows the magnetic field strength in a human perceptible representation, such as by displaying the measured magnetic field strength |B₀| as a numerical value with units of magnetic field, or by displaying a bar whose length is proportional to the measured magnetic field strength |B₀|, or so forth.

The magnetic field readout device 60 can be embodied in various ways. In the illustrative embodiment of FIG. 1, the magnetic field readout device 60 is embodied by a computer 70 having a digital processor (not shown) programmed by suitable software to implement the computation components 62, 64 and computational aspects for the display device 66, and a computer screen 72 for displaying the human-perceptible representation of the measured magnetic field strength |B₀|. In other embodiments, the magnetic field readout device 60 may be otherwise embodied, for example as a handheld magnetometer control unit including a digital processor and a dedicated LCD display or other dedicated display. Optionally, the computer 70 or the handheld magnetometer control unit may also include a printed circuit card or other electronic component that embodies other portions of the magnetometer, such as the VCO 30, the readout sub-circuit 40 of the detector, the oscillator 50, or so forth.

The magnetic field probe including at least the sample 10 and coil 22 making up the inductor 20 and the beam source 12 arranged to illuminate the sample 10, and optionally further including the radio frequency coil or antenna 52 providing the optional AB modulation, and/or the capacitor 26 or other resonant circuit component or components, and optionally further including various components of the radio frequency generator and/or detector, is suitably configured for insertion into the magnetic field B₀ to be measured, and hence may be, for example, at the tip of a wand, or designed for insertion in a bore of a magnetic resonance scanner, or so forth.

Performance of the magnetometer depends upon orientation of the probe respective to the direction of the magnetic field B₀ to be measured. In some embodiments the probe is handheld or can otherwise be moved to be oriented respective to the magnetic field B₀ in order to obtain the best magnetometer signal. In other embodiments, an array of samples each comprising an instance of the inductor 20 form an array with different orientations, for example arranged in a planar hemispherical configuration or in a three-dimensional half-sphere configuration, and the magnetometer includes further circuitry (not shown) to select the array element providing the best magnetometer signal.

With reference to FIG. 3, an illustrative example of the beam source 12 is shown. A light source 80 produces light (for example, monochromatic, polychromatic, or broad spectrum visible light, ultraviolet light, infrared light, or so forth, selected to be absorbed by the selected nuclear species of the sample 10) that is input to a beam expander 82. In some embodiments, the light source 80 is a white light source. The beam expander 82 includes an entrance collimator 84 for collimating the emitted light into a narrow beam, a concave or dispersing lens 86, a refocusing lens 88, and an exit collimator 90 through which the least dispersed frequencies of light are emitted. Other configurations are contemplated for the beam expander 82. After the beam expander 82, the light beam is circularly polarized by the combination of a linear polarizer 94 followed by a quarter wave plate 96. Using circularly polarized light is optional. Other optical preparation operations besides the illustrated beam expansion and circular polarization are contemplated, such as beam collimation, wavelength-selective filtering, intensity modulation, or so forth.

The circularly polarized light is passed through a phase hologram 100 or other component configured to impart orbital angular momentum (OAM) to the light. Some suitable embodiments of the phase hologram 100 are disclosed, for example, in Elgort et al., WO 2009/081360 A1; Albu et al., WO 2009/090609 A1; and Albu et al., WO 2009/090610 A1; each of which is incorporated herein by reference in its entirety. The phase hologram 100 imparts OAM and spin to an incident beam. In some embodiments, the phase hologram 100 imparts an OAM value l of at least l=10 to the beam. In some embodiments, the phase hologram 100 imparts an OAM value of about l=40 or higher to the light beam. In some embodiments, the phase hologram 100 is a computer generated element that is physically embodied as a spatial light modulator, such as a liquid crystal on silicon (LCOS) panel. In one suitable LcoS panel embodiment of the phase hologram 100, the panel has 1280×720 pixels, of area 20×20 μm², with a 1 μm cell gap. In other embodiments, the phase hologram 100 is embodied by other optics, such as combinations of cylindrical lenses or wave plates. If a spatial light modulator embodiment is employed, then the imparted OAM is optionally software-configurable under control of the computer 70 or another suitably programmed digital processor.

In some embodiments, not all of the light that passes through the holographic plate 100 is imparted with OAM and spin. For example, some OAM-imparting holographic plates have the effect of diffracting the light into different diffraction spot or regions, for example in an Airy pattern. For diffraction by the holographic plate 100 into an Airy pattern, the 0^{th} order diffraction does not have any imparted OAM and the different higher order diffraction spots have different OAM values l, with the maximum probability of OAM interaction being obtained for a light beam with a radius close to the Airy disk radius, and the total OAM in all diffraction spots or regions summing to zero in compliance with conservation of momentum. Accordingly, in the illustrative embodiment of FIG. 3 a spatial filter or beam stop 104 is placed after the holographic plate 100 to block all diffraction spots or regions except for those carrying light of a desired OAM value l. The selected diffracted beam or beams carrying the desired OAM value l are collected and collimated or focused onto the sample 10 as diagrammatically illustrated illumination 14 by concave mirrors 106, 108 and a microscope objective lens 110, as illustrated, or by another optical configuration.

Optionally, optical fibers (not illustrated) may be included in one or more portions of the optical train of the light source 12, or to convey the light beam 14 to the sample 10, in order to provide flexibility in the design of the light source 12 and or to provide flexibility in the relative positioning of the light source 12 and the sample 10. Various other optical configuration variations are also contemplated.

The embodiment of FIG. 1 is a continuous wave (CW) NMR magnetometer employing hyperpolarization of the target or selected nuclear species of the sample 10 in which the hyperpolarization is achieved using a light beam having orbital angular momentum (OAM). Other NMR magnetometer configurations employing hyperpolarization is achieved using a light beam having OAM are also contemplated.

With reference to FIGS. 4 and 5, another illustrative NMR magnetometer employing hyperpolarization achieved by light having OAM is shown. The NMR magnetometer diagrammatically shown in FIG. 4 employs a pulsed NMR mode. In the pulsed approach, instead of sending a continuous RF signal that scans a range of frequencies, the pulsed NMR magnetometer uses single broadband radio frequency pulse to rotate the nuclear magnetic moment of the selected nuclear species of the sample 10 (which is aligned along the magnetic field B₀ to be measured at equilibrium) out of alignment with B₀. The nuclei then precess around B₀ at the precessional frequency until equilibrium conditions return, in a process called a free induction decay (FID). With reference to FIG. 4, the sample 10 is shown in electromagnetic coupling with a radio frequency coil or antenna 150 that is selectively coupled with either a broadband radio frequency transmitter 152 or with a broadband radio frequency receiver 154 via radio frequency switching circuitry 156. A magnetometer controller 160 controls the beam source 12 to generate the illumination 14 with OAM.

During an NMR excitation phase the controller 160 causes the receiver 154 to detune from the resonance frequency (if needed to avoid overloading the receiver during the transmit phase), causes the switching circuitry 156 to operatively connect the transmitter 152 with the antenna or coil 150, and causes the transmitter 152 to input radio frequency energy to the hyperpolarized selected nuclear species of the sample 10 over a broadband encompassing the range of radio frequencies to be probed, that is, encompassing the range of frequencies F=|B₀|/γ corresponding to the range of magnetic field strengths |B₀| intended to be within the measurement range of the magnetometer.

After the excitation, the magnetometer controller 160 performs a readout phase by causing the switching circuitry 156 to operatively disconnect the transmitter 152 from the antenna or coil 150 and to operatively connect the receiver 154 to the antenna or coil 150, and causing the broadband radio frequency receiver 154 to acquire the free induction decay (FID) signal. With brief reference to FIG. 5, a representative FID signal S_{FID} is diagrammatically shown. The FID signal is processed by a fast Fourier transform (FFT) processor 164 to generate a FFT spectrum of the FID signal. With brief reference again to FIG. 5, a representative FFT spectrum FFT_{FID} is diagrammatically shown, which shows the expected result of a single strong FFT peak corresponding to the NMR frequency of the selected nuclear species of the sample 10 at the magnetic field strength |B₀| of the magnetic field in the sample 10. A frequency peak detector 166 detects the FFT peak and hence detects the NMR frequency. Optionally, the FFT processor 164 can be replaced by a discrete Fourier transform (DFT) processor or another type of spectral analyzer. It is also noted that commercially available FFT processors sometimes include a built-in peak detector, in which case such an FFT processor can embody both the FFT processor and peak detector components 164, 166.

With continuing reference to FIG. 4, once the NMR frequency is determined the processing is the same as that shown in FIG. 1. The magnetic field calculator 64 determines the magnetic field strength |B₀| based on the relationship |B₀|=F/γ where F is the detected NMR frequency and γ is the gyrometric ratio for the target or selected nuclei of the sample 10. The display device 66 shows the magnetic field strength in a human perceptible representation, such as by displaying the measured magnetic field strength |B₀| as a numerical value with units of magnetic field, or by displaying a bar whose length is proportional to the measured magnetic field strength |B₀|, or so forth.

In the embodiment of FIG. 4, the antenna or coil 150 is used for both transmit and receive phases, as enabled by the switching circuitry 156. In an alternative embodiment (not shown), separate transmit and receive coils or antennae can be provided, in which case the switching circuitry is omitted.

The illustrated magnetometers of FIGS. 1 and 4 provide an output in the form of a display of the measured magnetic field strength. More generally, the magnetometer can include a signal output generator configured to output a signal indicative of magnetic field strength based on the detected frequency of nuclear magnetic resonance. For example, in some embodiments the signal output generator is a digital output that sends a digital value indicative of magnetic field strength to another device, such as a monitoring device, without actually displaying the digital value. As another example, in some embodiments the signal output generator is a digital output that stores a digital value indicative of magnetic field strength, again without actually displaying the digital value. In other embodiments, the signal indicative of magnetic field strength may be displayed and stored, or may be displayed and sent to another device, or may be displayed, stored, and sent to another device.

This application has described one or more preferred embodiments. Modifications and alterations may occur to others upon reading and understanding the preceding detailed description. It is intended that the application be construed as including all such modifications and alterations insofar as they come within the scope of the appended claims or the equivalents thereof.

1. An apparatus comprising:
a magnetometer including:
a sample comprising a selected nuclear species,
an optical source configured to hyperpolarize the selected nuclear species of the sample by illuminating the sample with optical radiation having orbital angular momentum,
a radio frequency generator configured to input radio frequency energy to the hyperpolarized selected nuclear species of the sample over a probed range of radio frequencies,
a detector configured to detect a frequency of nuclear magnetic resonance excited in the hyperpolarized selected nuclear species of the sample by the input radio frequency energy, and
a signal output generator configured to output a signal indicative of magnetic field strength based on the detected frequency of nuclear magnetic resonance.

2. The apparatus as set forth in claim 1, wherein:
the radio frequency generator is configured to sweep the input radio frequency energy over the probed range of radio frequencies; and
the detector comprises a resonant electrical circuit including at least one of (i) an inductor having the sample as a core of the inductor and (ii) a capacitor having the sample as a dielectric spacer, the detector configured to detect the frequency of nuclear magnetic resonance based on a signal generated by the resonant electrical circuit.

3. The apparatus as set forth in claim 1, wherein:
the radio frequency generator is configured to input broadband radio frequency energy to the hyperpolarized selected nuclear species of the sample wherein the broadband radio frequency energy encompasses the probed range of radio frequencies; and
the detector comprises a radio frequency coil configured to detect nuclear magnetic resonance emanating from the sample and a spectrum analyzer configured to determine the frequency of the nuclear magnetic resonance detected by the radio frequency coil.

4. The apparatus as set forth in claim 1, wherein the optical source is configured to hyperpolarize the selected nuclear species of the sample by illuminating the sample with optical radiation having orbital angular momentum and circular polarization.

5. The apparatus as set forth in claim 1, wherein the optical source is configured to hyperpolarize the selected nuclear species of the sample by illuminating the sample with optical radiation having orbital angular momentum l of at least l=10.

6. The apparatus as set forth in claim 1, wherein the sample comprises water and the selected nuclear species comprise ¹H nuclei.

7. The apparatus as set forth in claim 1, wherein the sample comprises heavy water containing ²H₂O molecules and the selected nuclear species comprise ²H nuclei.

8. The apparatus as set forth in claim 1, wherein the selected nuclear species is selected from a group consisting of the isotopes ¹H, ²H, ¹³C, ¹⁴N, ¹⁹F, ²³Na, ²⁷Al, and ³¹P.

9. The apparatus as set forth in claim 1, wherein the signal output generator comprises:
a display device showing the magnetic field strength.

10. The apparatus as set forth in claim 1, wherein the sample has a volume of about 100 cubic microns or less.

11. The apparatus as set forth in claim 1, wherein the sample has a volume of about 10 cubic microns or less.

12. A method comprising:
hyperpolarizing a selected nuclear species of a sample by illuminating the sample with optical radiation having orbital angular momentum;
generating nuclear magnetic resonance of the hyperpolarized selected nuclear species of the sample;
determining a frequency of the generated nuclear magnetic resonance; and
outputting a signal indicative of magnetic field strength based on the determined frequency of the generated nuclear magnetic resonance.

13. The method as set forth in claim 12, wherein the generating comprises inputting radio frequency energy to the sample including sweeping the input radio frequency energy over a probed range of radio frequencies.

14. The method as set forth in claim 12, wherein the generating comprises inputting broadband radio frequency energy to the sample wherein the broadband radio frequency energy encompasses a probed range of radio frequencies.

15. The method as set forth in claim 12, wherein the hyperpolarizing comprises:
hyperpolarizing the selected nuclear species of the sample by illuminating the sample with optical radiation having orbital angular momentum l of at least l=10.

16. The method as set forth in claim 12, wherein the selected nuclear species comprise ¹H nuclei.

17. The method as set forth in claim 12 wherein the selected nuclear species comprise ²H nuclei.

18. The method as set forth in claim 12, wherein the selected nuclear species is selected from a group consisting of the isotopes ¹H, ²H, ¹³C, ¹⁴N, ¹⁹F, ²³Na, ²⁷Al, and ³¹P.

19. The method as set forth in claim 12, wherein the outputting comprises:
displaying the magnetic field strength as a numerical value with units of magnetic field on a display device.

20. The method as set forth in claim 12, wherein the outputting comprises:
displaying the magnetic field strength on a display device.
